(19) United States
(12) Patent Application Publication
(10) Pub. No.: US 2008/0164466 A1
(43) Pub. Date: Jul. 10, 2008

(54) LIGHT EMITTING DEVICES WITH A ZINC OXIDE THIN FILM STRUCTURE

(76) Inventors: Brian Rioux, Kanata (CA); Jean-Paul Noel, Ottawa (CA)

Correspondence Address: TEITELBAUM & MACLEAN, 280 SUNNYSIDE AVENUE, OTTAWA, ON, K1S 0R8, omitted

(21) Appl. No.: 11/971,566

(22) Filed: Jan. 9, 2008

Related U.S. Application Data
(60) Provisional application No. 60/884,266, filed on Jan. 10, 2007.

(51) Int. Cl. H01L 33/00

(52) U.S. Cl. 257/43; 438/38; 257/E33.019

(57) ABSTRACT

The present invention relates to a sol-gel deposition/heat treatment process, which consistently produces polycrystalline direct bandgap semiconductor, e.g. ZnO, thin films exhibiting a photo luminescent (PL) spectrum at room temperature that is dominated by a single peak, e.g. in the ultraviolet part of the spectrum, in which the PL intensity of the bandgap emission is more than approximately 40 times greater than any deep-level defect emission peak or band. The present invention incorporates such direct bandgap semiconductor, e.g. ZnO, polycrystalline thin films produced by the method of the present invention into electro-luminescent devices that exhibit similarly high ratios of bandgap/deep-level defect emission intensity.

### CROSS-REFERENCE TO RELATED APPLICATIONS

The present invention claims priority from U.S. Patent Application No. 60/884,266 filed Jan. 10, 2007, which is incorporated herein by reference.

### TECHNICAL FIELD

The present invention relates to light-emitting semiconductor thin film device, and in particular to direct-bandgap semiconductor material, such as a zinc-oxide (ZnO) or a ZnO alloy, with a dopant for populating the direct bandgap semiconductor material with free-exciton binding centers in concentrations above native defect concentration.

### BACKGROUND OF THE INVENTION

Zinc oxide (ZnO) is a multifunctional semiconductor material which has been used in various areas, including phosphors, piezoelectric transducers, surface acoustic wave devices, gas sensors, and varistors. With a band gap of approximately 3.3 eV, ZnO is similar to that of Gallium Nitride (GaN), but with a higher free-exciton binding energy of 60 meV, compared to 25 meV for GaN, thereby favoring efficient free-exciton emission at room temperature. Free-excitons are coupled electron-hole pairs not bound to anything else other than themselves, i.e. they are perfect electric dipoles. In a semiconductor, they are equivalent to efficiently stored potential (light) energy, akin to a “light capacitor”. The high free-exciton binding energy in ZnO means that free-excitons can exist in ZnO at temperatures up to approximately 700° K, or 430° C., at which point they begin to “boil” apart and free-exciton recombination can no longer occur. Accordingly, ZnO has been recognized as a promising material for light emitting devices that are both efficient and practical at room temperature. In comparison, the low free-exciton binding energy in GaN, i.e. 25 meV, results in the free-excitons “boiling” apart at or below room temperature, making GaN unsuitable for free-exciton light emission.

Another important property of ZnO is its high optical transmittance in the visible and near ultra-violet (UV) regions, even when it is doped with certain atoms, e.g. Aluminum (Al), which are used to increase the electrical conductivity of the zinc oxide film, thereby forming a transparent conducting oxide (TCO). Indium-tin oxide (ITO) is currently the industry standard for TCO material in flat panel displays, solar cells, etc; however, the global supply of indium metal is limited, thereby causing the price for the refined form of indium to be considerably higher than zinc, e.g. US$700/kg cf. for indium compared to US$4.00/kg for Zn, as of December 2006. Many leading electronics designers and manufacturers, e.g. Samsung, therefore have active development programs that aim to replace ITO with alternative TCO's, such as ZnO.

Zinc-oxide films have been synthesized by numerous methods, such as metal-organic chemical vapor deposition, molecular beam epitaxy, magnetron sputtering, pulsed laser deposition, atomic layer deposition, spray pyrolysis. Low temperature deposition is required in most flat-panel processes in order to avoid reactive and elemental diffusion of different layers and to protect substrates, such as polymers. Among these methods, ZnO films can be synthesized at temperature as low as 100° C. by metal-organic chemical vapor deposition and atomic layer deposition, and even at room temperature by magnetron sputtering and pulsed laser deposition. The high kinetic energies of growing precursors in the last two methods are believed to play a key role in the realization of low temperature deposition critical to the flat panel display industry.

The required material properties for producing ZnO films suitable as an efficient light emitter, as opposed to a TCO, are more stringent, which has hampered the development of ZnO light emitters over the past 40 years or so. Specifically, the main issue has been the formation of undesirable native defects in ZnO, e.g. vacancies and interstitials of both Zinc and Oxygen atoms, which are deep-level defects that reduce the efficiency of emission at the bandgap energy by trapping the free excitons and substantially reducing the energy of any subsequent radiative emission, or favoring non-radiative emission, i.e. stored bandgap energy is lost to other undesirable pathways such as heat. Reducing (during process) and maintaining (post-process) the undesirable deep-level defect concentration to low values, while simultaneously providing (during process) an appropriate concentration of desirable shallow optical binding centers to prevent the free excitons from migrating to the deep-level defects, are the key elements needed to enable bandgap (or near bandgap) radiative recombination to dominate.

An object of the present invention is to overcome the shortcomings of the prior art by providing a light emitting structure comprising an active layer of a direct bandgap semiconductor material, such as ZnO or ZnO alloy, with a free-exciton binding energy greater than 25 meV, enabling free-excitons to exist at room temperature, with a dopant for populating the ZnO material with free-exciton binding centers in concentrations above native defect concentration.

### SUMMARY OF THE INVENTION

Accordingly, the present invention relates to a light emitting structure comprising:

an active layer structure including:

a direct bandgap semiconductor material with a free-exciton binding energy greater than 25 meV, enabling free-excitons, comprising an electron and a hole, to exist at room temperature, and

a dopant for populating the direct bandgap semiconductor material with free-exciton binding centers in a concentration greater than or equal to a native defect concentration in the direct bandgap semiconductor material, wherein the binding energy of either the electron or the hole of each of the free excitons to the dopant binding center is also greater than 25 meV; and

an excitation source or mechanism for generating electron-hole pairs in the direct bandgap semiconductor material to produce substantial populations of excitons;

whereby the binding centers provided by the dopant increase probability of free-exciton to bound-exciton formation in the direct bandgap semiconductor material for generating efficient near-bandgap-emission of light.

Another aspect of the present invention relates to a method of forming a direct bandgap semiconductor material polycrystalline film comprising the steps of:

a) providing a direct bandgap semiconductor material precursor;

b) providing a dopant precursor for populating crystallites within the polycrystalline film with optically active free-exciton binding centers in concentrations above a native defect concentration;

c) placing the direct bandgap semiconductor material precursor in a solvent with a stabilizing compound forming a mixture;

d) dissolving the dopant precursor in the mixture;

e) dispensing the mixture onto a wafer forming the direct bandgap semiconductor material film with dopant therein; and

f) baking the film to fully crystallize the film, promote grain growth, and minimize the concentration of native intra-crystal defects, thereby substantially increasing the probability that free excitons will encounter and bind to the optically active free exciton binding centers before encountering a defect site.

### BRIEF DESCRIPTION OF THE DRAWINGS

The invention will be described in greater detail with reference to the accompanying drawings which represent preferred embodiments thereof, wherein:

FIG. 1 is a magnified plan view of a polycrystalline ZnO:Al thin film using transmission electron microscopy;

FIG. 2 illustrates room temperature photo-luminescence (PL) of a ZnO:Al polycrystalline thin film produced by a sol-gel deposition process in accordance with the present invention;

FIG. 3 illustrates room temperature PL of a commercially available undoped ZnO wafer substrate;

FIG. 4 illustrates room temperature PL of an undoped zinc oxide thin film vs a zinc oxide thin film doped with 0.4 at % aluminum;

FIG. 5 illustrates room temperature PL of a zinc oxide thin film doped with 0.1 at % aluminum;

FIG. 6 illustrates room temperature PL of a zinc oxide thin film doped with 3.2 at % aluminum;

FIG. 7a is a plot of maximum UV PL intensity vs atomic % of aluminum in ZnO;

FIG. 7b is a plot of PL intensity from radiative defects vs atomic % of aluminum in ZnO;

FIG. 7c is a plot of the ratio of maximum UV PL intensity to maximum PL intensity from radiative defects vs atomic % of aluminum in ZnO;

FIG. 8 is a cross-sectional schematic view of a light emitting device in accordance with the present invention; and

FIG. 9 is a cross-sectional schematic view of a second type of light emitting device in accordance with the present invention.

### DETAILED DESCRIPTION

The present invention relates to direct-bandgap, semiconductor-material, thin films, such as zinc oxide (ZnO) or ZnO alloyed, e.g. with beryllium, cadmium and magnesium, for use in producing efficient electro-luminescent devices by enhancing the intensity of the bandgap light emission compared to the deep level (defect) light emission typically observed to be dominant in most direct-bandgap semiconductor devices, by providing a dopant with high concentrations of free-exciton binding centers. Specifically, the present invention is achieved by using process conditions for simultaneously satisfying all of the following materials requirements during fabrication of the electro-luminescent device or the optically active layer:

(1) minimizing the concentration of point defects within the direct-bandgap, semiconductor material, e.g. ZnO, optically active layer (film), comprising a single crystal or polycrystalline grains, in particular the native defects involving vacancies and interstitials, e.g. of Zn and/or O atoms, and their complexes by providing a high temperature baking step detailed below;

(2) incorporating and activating free-exciton binding centers, i.e. optical centers, within the direct bandgap semiconductor optical-emitter film, e.g. ZnO: (a) in a concentration that is substantially equal to or greater than the total local (intra-crystal) defect concentration; and (b) with a binding energy of each exciton's electron or hole, i.e. greater than or equal to 25 meV, which enables the large population of free-excitons (now bound excitons) to exist at the required temperature, e.g. room temperature. Dynamically, the free excitons are formed immediately upon electron-hole generation, and remain stable in direct bandgap semiconductor, e.g. ZnO, at room temperature because of the 60 meV mutual attraction (binding energy) therebetween. A dopant is provided, for forming the optical centers, which act as binding sites, each of which also has a binding energy greater than or equal to 25 meV, for either the electron or the hole of each exciton. High concentrations of free-exciton binding centers serve to greatly increase the probability that free-excitons, i.e. electron-hole pairs created by a means for generating electron-hole pairs, (e.g. electrodes for electron/hole impact ionization, a PN junction for electron/hole injection, or a light source, such as a laser, for photon absorption) will encounter and bind to the optically active centers before encountering an intra-crystal defect site. The net result is a large increase in the efficiency of the total radiative pathway [electron-hole pair generation→free exciton (FE) formation→bound exciton (BE) formation→photon generation], due to the presence of the intermediate free exciton state, which is absent in most semiconductors at room temperature, and the enhanced probability of FE→BE formation due to the presence of exciton binding centers with energy greater than 25 meV in concentrations at or above any defect concentrations;

(3) maximizing the grain size in polycrystalline films, thereby substantially increasing the probability that free excitons in the direct-bandgap, semiconductor material, e.g. ZnO, film will encounter and bind to the optically active centers before encountering a grain boundary defect site or accumulated charge at the edges of the depletion layers formed by the grain boundaries by providing a high temperature baking step detailed below; and

(4) passivating any exposed surfaces of the direct-bandgap, semiconductor material, e.g. ZnO, film during process with a suitable passivant, such as SiN or SiO₂ dielectric material, to prevent interaction with ambient air and/or water by providing a passivation step detailed below. Without the surface passivation layer, the initially-high PL intensity of freshly-prepared direct-bandgap, semiconductor material, e.g. ZnO, films tend to degrade by as much as 30% after 24 hours exposure to ambient air, and a further 20% reduction after a total of 48 hours exposure. The reduction is most likely the result of native defect formation, in particular those involving oxygen atoms, since they are in kinetically-limited reactions with O₂ or H₂O molecules at the exposed surfaces, while the system moves toward thermodynamic equilibrium, which for ZnO at room temperature means an inherently high concentration of native defects.

ZnO:Al Solgel Process Description

Source materials for an exemplary process according to the present invention are zinc (Zn) acetate, for the main metal constituent, and aluminum (Al) nitrate, as the dopant. Using the chemical formula weights, a calculated quantity of Zn acetate is weighed out on a microbalance to achieve the target molar concentration, e.g. 0.3M. Aluminum nitrate is similarly weighed out to achieve a desired dopant ratio Al/(Al+Zn), e.g. ranging up to 0.05 or 0.10, i.e. 5 at % or 10 at %, whereby the low end of the range is limited by the ability to accurately weigh minute quantities of the dopant source powder on the microbalance. The Zn acetate powder is then added to a solvent, e.g. methoxy-ethanol, into which was previously mixed a stabilizing compound, e.g. mono-ethanol-amine (MEA), in the ratio of MEA/Zn=1. The dopant source powder, aluminum nitrate, is then added, and the mixture stirred until all solids have dissolved, which may require heating the mixture up to 90° C., into a clear solution.

When cooled to room temperature, the clear solution is drawn up into a dispensing syringe, and a 0.2 μm dispense filter applied. Using a spin-on process similar to standard photo-resist processing, the solution is dispensed onto a static wafer, the spin speed is ramped up to the target value, e.g. 3000 rpm, thus producing a uniform thin layer of the solution. A bake process to drive off the solvent is then applied, which presently occurs in two steps: first at 60° C. to 90° C., ideally 70° C., in air for up to 5 to 10 minutes, then at 250° C. to 350° C., ideally 300° C., in air for 5 to 10 minutes or more. Shorter times for this step has been shown to result in lower intensity PL films. The resulting film thickness is too thin, approximately 15 nm, to be useful for most applications, so the spin-on/bake process sequence described above is repeated until the target thickness is achieved. Typically 10 to 20 repeats are used, resulting in a film thickness between 150 nm and 300 nm.

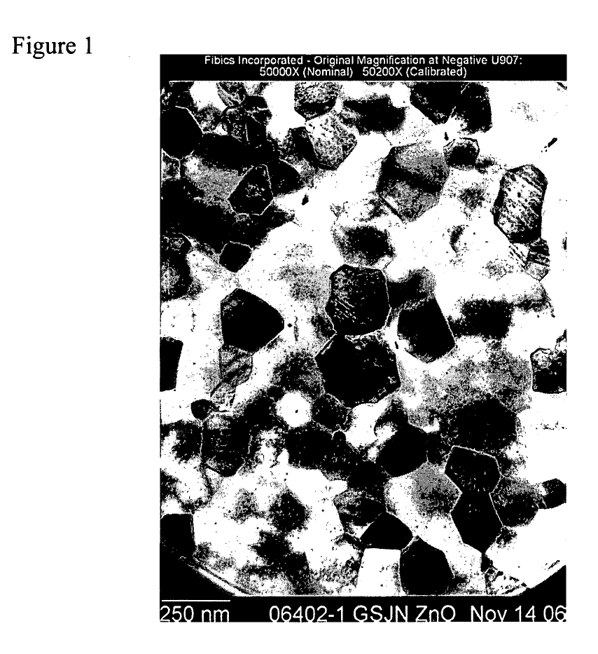

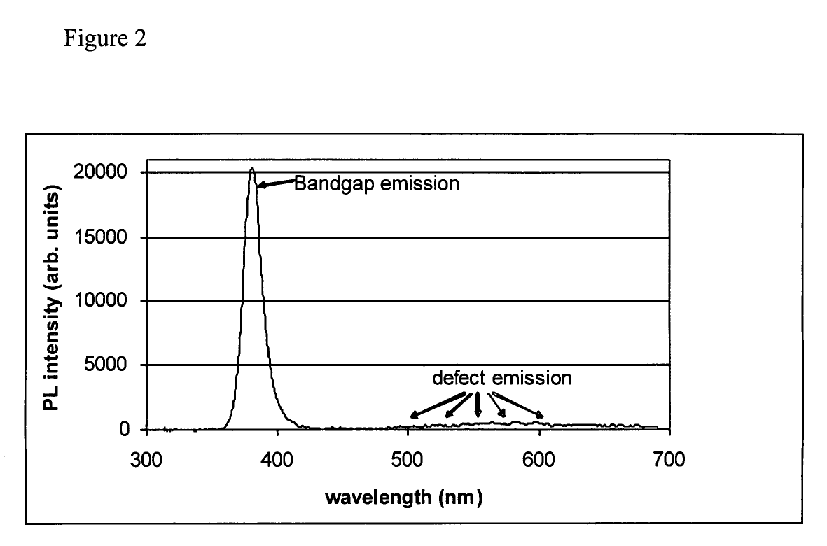

The final film stack on the wafer then undergoes a higher-temperature bake process to fully crystallize the film, promote grain growth, and most importantly, minimize the concentration of native intra-crystal defects, while decreasing the conductivity, thereby eliminating its ability to be a TCO. Currently the baking process is also a two step process, but in a tube furnace rather than on a hotplate: e.g. 350° C. to 550° C., preferably 400° C. to 500° C., or ideally 450° C. in air for 80 to 100 minutes or ideally 90 minutes, then ramped up to between 800° C. to 1200° C., preferably 1000° C., or higher in Nitrogen (N₂) and held for 30 minutes or more before cool down to ambient air. The resulting ZnO:Al thin film is polycrystalline, with well-formed, distinct grains approximately 0.25 um in size (see FIG. 1 for plan-view transmission electron microscopy), and a preferred orientation of the grains in the (0001) direction, as measured by x-ray diffraction. With reference to FIG. 2, characterization by photoluminescence with a HeCd laser gives a single dominant peak of bandgap emission near 385 nm with 40 times greater intensity of bandgap emission compared to any defect related emission in the middle of the bandgap.

FIG. 2 illustrates room temperature PL of a ZnO:Al polycrystalline thin film produced by the aforementioned sol-gel deposition process with a final 1000° C. anneal in N₂. The excitation source, i.e. the means for generating the electron-hole pairs, was a HeCd laser with 325 nm emission at 20 mW/cm². The spectrometer was an Avantes unit with 1 second integration time. The resulting ratio of bandgap emission intensity to deep level defects is greater than 40:1.

The bandgap emission wavelength of 385 nm for ZnO shown in FIG. 2 can be increasingly shifted down, e.g. to between 340 nm and 385 nm, (higher bandgap energy) with increasing amounts of magnesium (Mg) acetate added to the solution after the zinc acetate has dissolved, whereby Mg substitutes on the Zn atom sub-lattice, forming Zn₁₋ₓMgₓO ternary alloy, or can be increasingly shifted upward (lower bandgap energy, into the visible region), e.g. to between 385 nm and 500 nm, with increasing amounts of cadmium (Cd) acetate added to the solution after the zinc acetate has dissolved (Zn₁₋ₓCdₓO ternary alloys).

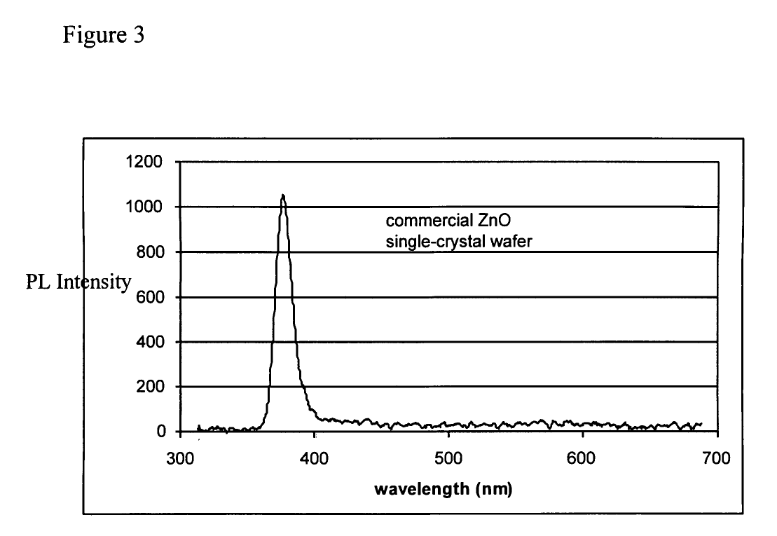

The process described above produces ZnO films with efficient luminescence, exhibiting approximately 20 times greater intensity compared to PL measurements of commercially available, single-crystal ZnO wafers, as illustrated in FIG. 3, because the process conditions for film deposition and annealing were designed to take advantage of the fact that free excitons in ZnO have an inherently short radiative lifetime, i.e. approximately 300 ps. The excitation source and spectrometer were identical to that used for FIG. 2, hence the “arbitrary units” for the PL intensity in FIGS. 2 and 3 are comparable. Although the specific atomic configuration of the aluminum containing optical centers formed at 1000° C. have not yet been identified, it is known with certainty that they are not the usual shallow donors associated with ZnO:Al (sometimes called AZO) used for TCO applications, since the ZnO thin films of the present invention have no measurable electrical conductivity (by four point probe), despite their superior optical emission properties. Accordingly, it is believed that the aluminum atoms are bound in a complex, perhaps as Al₂O₃ molecules. During their brief 300 ps lifetime in zinc oxide, free-excitons will migrate toward lower energy regions of their host crystal, i.e. in this case toward the nearest binding center. Populating the crystals with free-exciton binding centers in concentrations above the native defect concentration ensures that free-excitons will find the optical centers before the deep level defects. Comparing the PL peak position from an undoped ZnO single crystal wafer (see FIG. 3) with that from Al-doped films according to the present invention, a peak shift (at room temperature) is observed from 3.293 eV to 3.256 eV, respectively, from which the binding energy of the free-exciton binding center is estimated to be 37 meV. The PL intensity from the polycrystalline ZnO:Al films according to the present invention (FIG. 2) is approximately 20 times greater than from the commercially single-crystal ZnO wafer (FIG. 3). The 37 meV binding energy for the free exciton to the optical center in ZnO is consistent with efficient binding, and hence bound-exciton recombination, at room temperature, wherein the equivalent single particle energy at room temperature is approximately 25 meV. Other direct bandgap semiconductor materials with a binding energy above 25 meV could be used in place of zinc oxide. Other dopant atoms, such as erbium (Er) and cerium (Ce), can be incorporated as a source for free exciton binding centers, which also provide an enhancement in the PL intensity, but not as great an enhancement as aluminum in the present method. If the binding energy is too high, then the resulting emission is no longer near the bandgap, i.e. at a mid-gap level, and thereby associated with defects. The transition probability in such a case is expected to decrease. The measured binding energy for excitons to both erbium and cerium, compared to undoped ZnO, is approximately 6 meV.

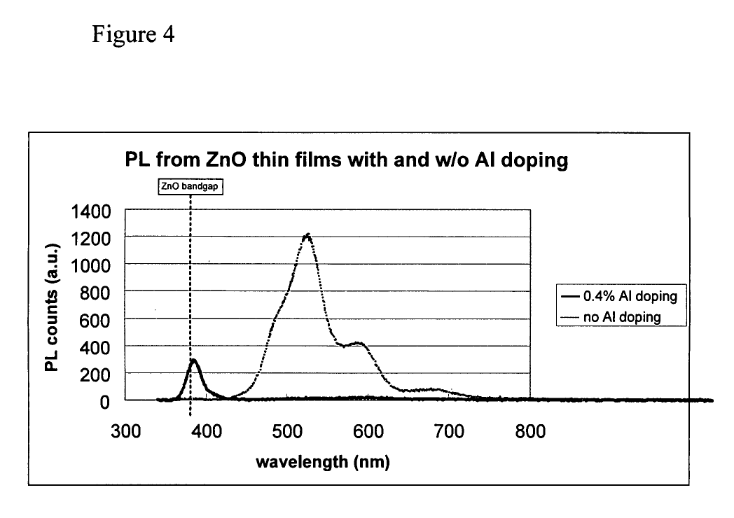

The photoluminescence (PL) response of first and second zinc-oxide films prepared by a spin-on technique are illustrated in FIG. 4. The starting solutions for each were the same in all respects, except for the addition of 0.4 at % aluminum (as Al nitrate) that was added to the second spin-on solution as a dopant (see solid line). Subsequent spin-on and thermal processing were identical for both films.

The first zinc-oxide film with no added aluminum has a photo-luminescent spectrum (dotted line) that is completely dominated by defect-related emission. In fact, no appreciable near-bandgap UV emission at or near 385 nm can be seen from the first zinc-oxide film without aluminum doping. The defect related peaks are observed in the visible part of the first spectrum as a low energy shoulder at approximately 480 nm, the primary peak at approximately 530 nm, i.e. the so-called “green band” associated with ZnO native defects, most likely Zn vacancies, a peak at approximately 590 nm, and a weak red peak at 680 nm.

In sharp contrast, the addition of aluminum as a dopant, in this case in a concentration of 0.4 at % Al/(Al+Zn), illustrated by the solid line in FIG. 4, shows the PL response to be dominated completely by near-bandgap emission of zinc oxide at or near 385 nm, with very little defect-related emission. This effect is due to the formation of exciton binding centers caused by the addition of the aluminum, with subsequent high temperature processing, e.g. the high temperature bake at 1000° C. The higher concentration of binding centers, relative to the high concentration of defects inherent to zinc oxide, enables trapping of free excitons before they can diffuse to defect-related centers and non-radiative centers, thereby increasing the emission efficiency at (or near) the bandgap energy.

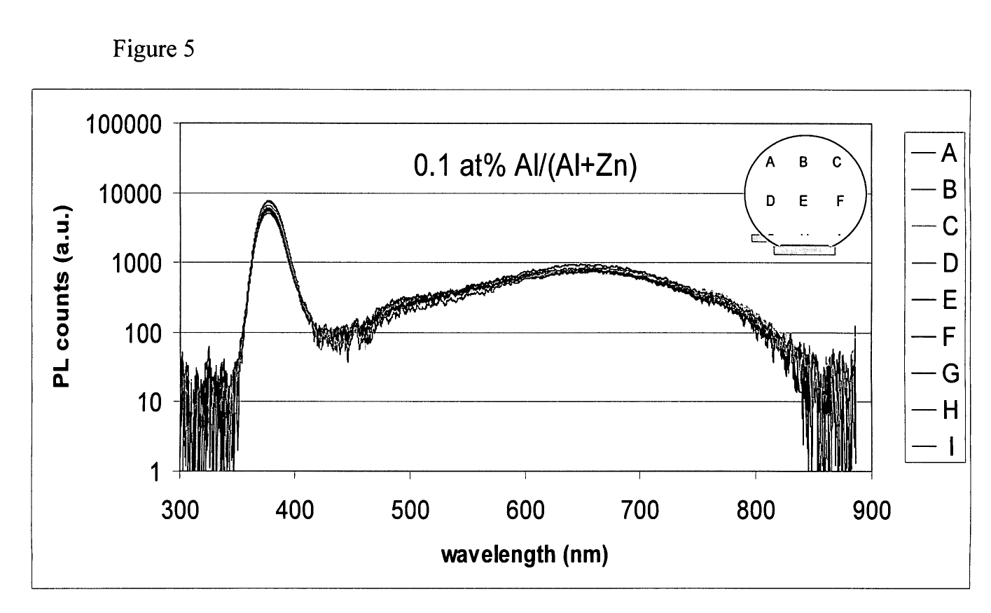

FIG. 5 illustrates photo-luminescent (PL) spectra taken from nine points across a two inch diameter silicon wafer coated with 1 um thermal SiO₂, then with a 200 nm zinc oxide active layer doped with 0.1 at % aluminum prepared by a spin-on process with subsequent annealing in N₂ at 1000° C. The nine plots are on a logarithmic ordinate scale. As with FIG. 4, which shows the ultraviolet (UV) emission peak (385 nm) dominating with the addition of aluminum dopant to 0.4 at %, FIG. 5 illustrates the PL with the aluminum dopant at 0.1 at %, whereby the UV emission peak at approximately 385 nm is again dominant. A ratio of approximately 8:1 or greater for the UV peak to the highest intensity of the broad radiative defect band, at approximately 650 nm, is observed.

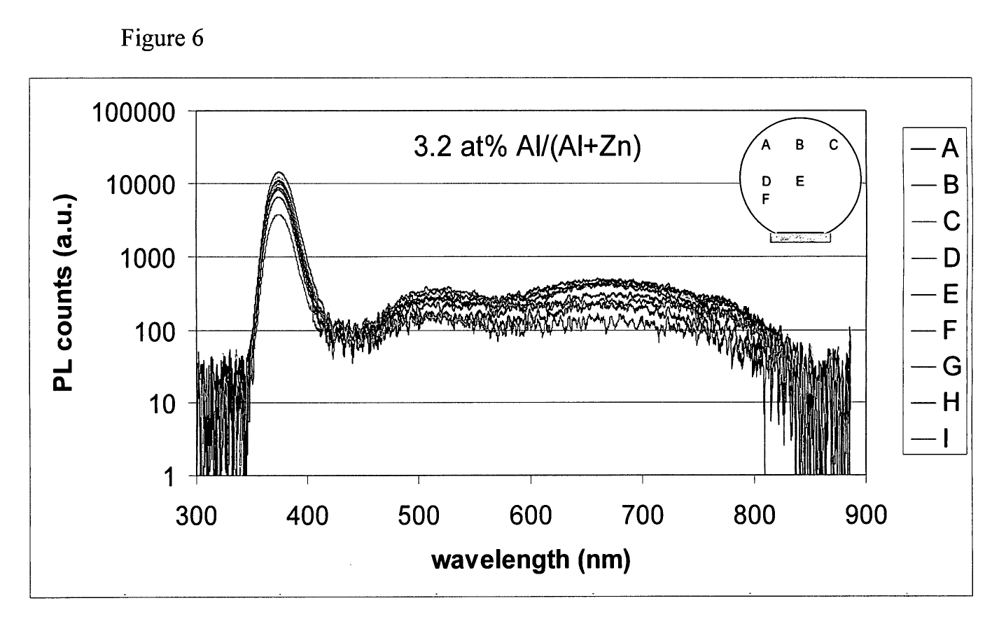

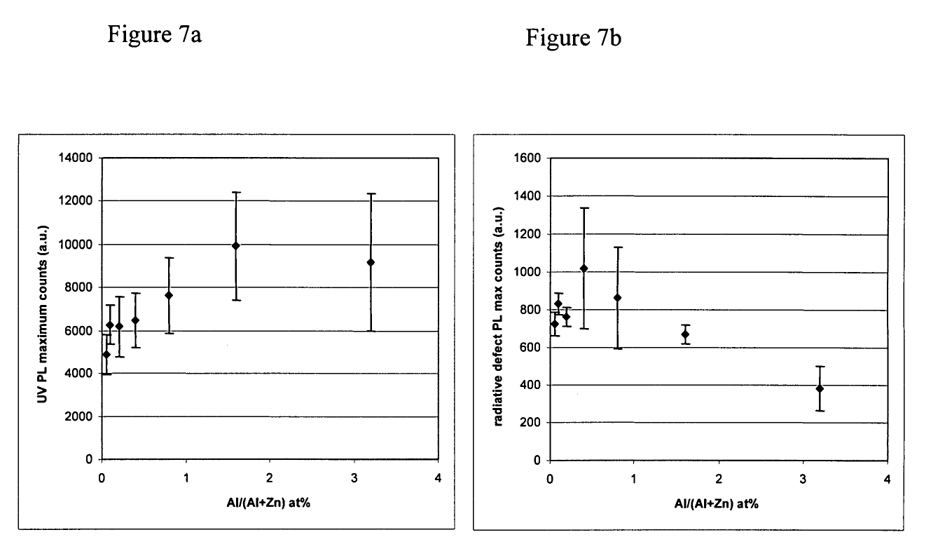

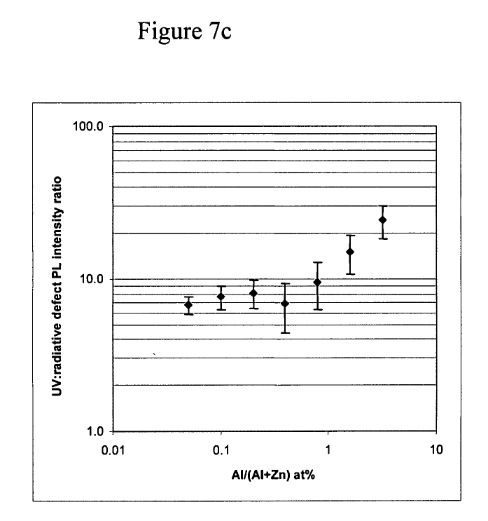

The wafer providing the PL of FIG. 5 was part of a series of seven wafers, each wafer having a different aluminum content in the zinc oxide film, spanning the range of 0.05 at % to 3.2 at %, the results of which are illustrated in FIGS. 7a to 7c. FIG. 6 illustrates a nine-point PL wafer map for the wafer of the series with highest aluminum content, i.e. 3.2 at %, in the zinc oxide film. The peak UV intensity illustrated in FIG. 6 is greater than that shown in FIG. 5, and the radiative defect band has two visible components, with peaks at approximately 530 nm and 680 nm, while the 590 nm defect band, as seen in FIG. 4, is absent. The intensity of either the 530 nm or the 680 nm band is lower than the single defect band seen in FIG. 5 with 0.1 at % aluminum doping. The larger spread between different points on the wafer observed in the PL spectra in FIG. 6 is due to the film with 3.2 at % aluminum exhibiting phase segregation behavior, which is clearly visible to the unaided eye and dark field microscope (images not shown).

FIGS. 7a, 7b and 7c summarize the statistical PL data from all seven wafers in the series as a function of aluminum content ranging from 0.05 at % to 3.2 at %. FIG. 7a plots the average and standard deviation of the PL peak intensity maxima in the UV part of the spectra, i.e. approximately 385 nm, versus aluminum content. The peak UV intensity generally increases with the aluminum content. FIG. 7b plots the average and standard deviation of the PL band intensity maxima in the radiative defect-related part of the spectra, i.e. approximately 450 nm—to 800 nm (whichever band has the highest intensity), versus aluminum content. The peak non-UV intensity generally decreases with aluminum content.

FIG. 7c plots on a log-log scale the average and standard deviation of the ratio of the UV to radiative-defect-related PL emission intensity maxima. A flat region between an aluminum content of 0.1 at % and 0.4 at % is observed, whereas between 0.4% and 3.2% there is a linear increase in the ratio with aluminum content. The results suggest that the concentration of radiative defects in the ZnO:Al films is in the range of 0.05% to 0.4%, i.e. similar to the aluminum content used, thereby causing the intensity to be invariant with aluminum content. At 0.4 at % Al and higher, the greater density of binding centers provided by the increasing concentration of aluminum atoms causes the intensity ratio to increase, which in turn causes the near-bandgap (UV) PL emission efficiency to increase.

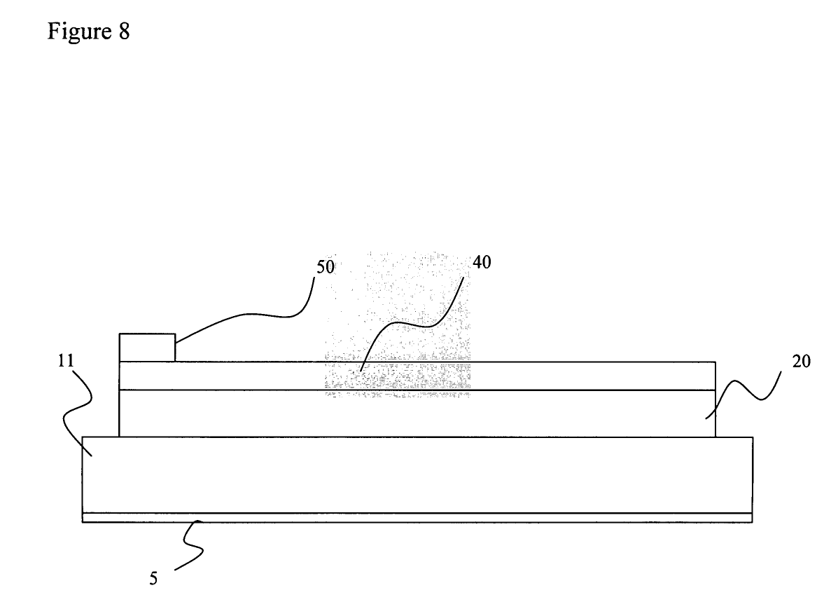

Using the ZnO layer described above, a multitude of semiconductor structures can be prepared. For example, a semiconductor structure is shown in FIG. 8, which shows a substrate 11, on which substrate is deposited an active layer structure 20 of the direct bandgap semiconductor material, e.g. ZnO or ZnO alloy doped material to make a carrier injection device structure.

The substrate 11, on which the active layer structure 20 is formed, is selected so that it is capable of withstanding high temperatures in the order of 1000° C. or more. Examples of suitable substrates include silicon wafers or poly silicon layers, either of which can be n-doped or p-doped (for example with 1×10²⁰ to 5×10²¹ of dopants per cm³), fused silica, zinc oxide layers, quartz, sapphire silicon carbide, or metal substrates. Some of the above substrates can optionally have a deposited electrically conducting layer, which can have a thickness of between 50 nm and 2000 nm, but preferably between 100 nm and 500 nm. The thickness of the substrate 11 is not critical, as long as thermal and mechanical stability is retained.

The active layer structure 20 can be comprised of a single or of multiple direct bandgap semiconductor material(s), e.g. ZnO or ZnO alloy, doped layers, as described above, each layer having an independently selected composition and thickness.

The active layer structure 20 preferably has an optically transparent current injection layer 40, e.g. electrically-conducting Aluminum Zinc Oxide (AZO) or Indium Tin Oxide (ITO), over top of the active layer structure 20 along with a back electrical contact 5 comprising either a single metal layer or a stack of metal layers. The top electrical contact 50 is similarly formed by either a single metal layer or a stack of metal layers. Preferably, the AZO or ITO layer 40 has a thickness of from 150 nm to 500 nm. Preferably, the chemical composition and the thickness of layer 40 are such that the semiconductor structure has a resistivity of less than 70 ohm-cm.

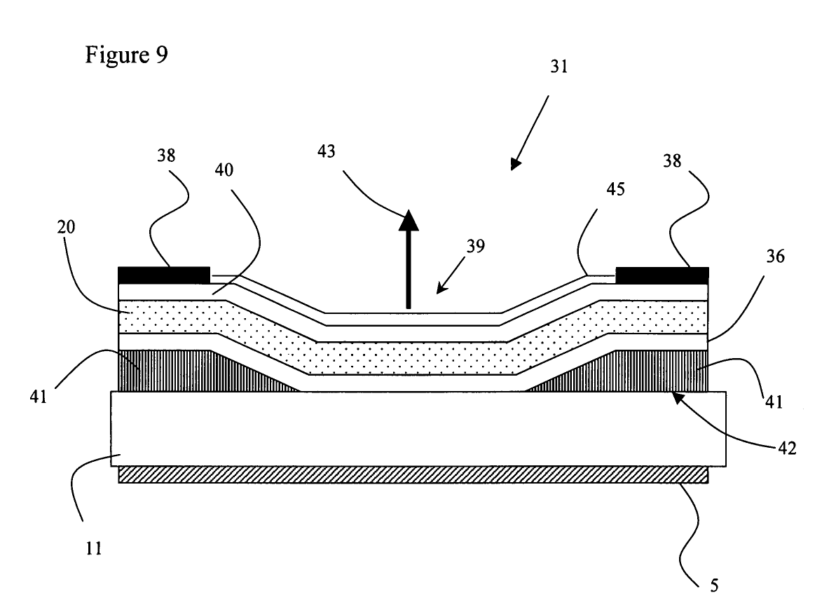

A UV emitter built as in FIG. 9 has similar applications to a UV-LED, but is differentiated from an LED by: (a) high-voltage AC operation, not low-voltage DC as for the device shown in FIG. 8; (b) no fundamental restriction on die size to make a large, bright die; and (c) inexpensive materials and growth systems compared to conventional LED materials. These characteristics are required to achieve inexpensive white light emitters, which would be created by adding some form of phosphor system to the device (for example, as part of an encapsulant) that converts the UV emission into visible light.

With reference to FIG. 9, an electro-luminescent device 31 in accordance with the present invention includes the conducting substrate 11, preferably comprising silicon, with the metal contact layer or layer stack 5 supported on one side thereof. A direct bandgap semiconductor material, e.g. ZnO (or alloyed), doped active layer structure 20 ideally between 10 nm and 1000 nm thick, is supported on the other side of the substrate 11, sandwiched between a dielectric layer 36 and a transparent electrode layer 40. An additional dielectric layer (not shown) can be disposed between the active layer structure 20 and the electrode layer 40. A metal contact layer or stack of metal layers 38 mounted on opposite transverse sides of the transparent electrode layer 40, forming a light emitting well 39 therebetween, enable an electrical field to be applied thereto. A layer of phosphor 45 can be disposed on top of the transparent electrode layer 40, as illustrated, or between the electrode layer 40 and the active layer structure 20 for converting the UV light emitted from the active layer structure 20 to visible light. Various kinds of phosphors can be used to produce different colors of light, including white light.

The light emitting wells 39 are isolated from the conducting portions of the substrate 11 by field oxide regions 41 disposed directly below the metal contacts 38, as disclosed in U.S. patent application Ser. No. 11/642,813, filed Dec. 21, 2006. In an exemplary embodiment, the dielectric layer 36 is 1 μm thick and comprised of silicon dioxide (SiO₂), but other dielectric layers and thicknesses, e.g. between 2 nm and 10 μm are feasible. Silicon nitride (Si₃N₄) prepared by low pressure chemical vapor deposition, is more suitable than SiO₂ due to the lower diffusion constant of zinc, thereby reducing void formation at the ZnO-dielectric interface due to high temperature processing; however, aluminum oxide, yttrium oxide, and hafnium oxide are some other possibilities. A reflective layer 42 can be provided between the substrate 11 and the dielectric layer 36 to reflect light back through the active layer structure 20 and out, as shown by arrow 43, to ensure maximum light emission efficiency of the device 31.

The zinc oxide active layer(s) in the active layer structure 20 is doped with exciton binding centers up to 20 at % of Al/(Al+Zn), or between 0.001 at % and 20.0 at %, preferably between 0.0.02 at % to 10.0 at %, and most preferably between 0.04 at % to 5.0 at % atomic percent, in order to provide optical binding centers to the free excitons when they are formed. The exciton binding centers prevent free excitons from diffusing toward and recombining at native defect centers, e.g. Zn and O vacancies and interstitials, which are known to be in relatively high equilibrium concentrations even in good-quality ZnO due to the high bandgap energy. The exciton binding centers are one or more of the elements selected from the group consisting of boron, aluminum, gallium, indium, thallium, nitrogen, phosphorous, arsenic, antimony, and bismuth, but preferably aluminum as herein described.

The electrode layer 40 is preferably a transparent conducting oxide (TCO) comprised of zinc oxide doped with aluminum (ZnO:Al), which is deposited by sputtering at temperatures less than approximately 400° C. so as to retain its electrical conductivity. The high electron concentration provided by the TCO 40 provides a significant source of electrons to initiate impact ionization in the active layer structure 20 when the field strength reaches threshold during bipolar operation.

The contact layer 5 and the metal contacts 38 are preferably comprised of aluminum, and are approximately 0.5 μm thick with a sheet resistance and specific contact resistance of approximately 40Ω/□ and 3E-4Ωcm², respectively. Alternatively, the contact layer may be a Ti/Au stack, or single Au layer.

A process for manufacturing the device 31 of FIG. 9, which emits UV light 43, includes first providing the substrate 11, and then depositing a layer of field dielectric (oxide) material thereon. In the next step, a portion of the field dielectric layer is removed forming the field dielectric (oxide) regions 41 and creating the device well area 39. The deposition and removal steps for the field dielectric layer can be replaced by a single step involving deposition of separate field dielectric regions 41. Then the dielectric layer 36, the active layer 20, the electrode layer 40, and the phosphor layer 45 (if wavelength conversion from UV is required) are deposited in sequence, followed by the electrical field applying features 5 and 38. Silicon nitride (Si₃N₄) or silicon dioxide (SiO₂) can be used for the dielectric layer 36; however, Si₃N₄, prepared by low pressure chemical vapor deposition, is the preferred method, due to the lower diffusion constant of Zn, thereby reducing void formation at the ZnO-dielectric interface due to high temperature processing. Other deposition methods include plasma-enhanced chemical vapor deposition, sputtering, and e-beam evaporation.

We claim:

1. A light emitting structure comprising:
an active layer structure including:
a direct bandgap semiconductor material with a free-exciton binding energy greater than 25 meV, enabling free-excitons, each comprising an electron and a hole, to exist at room temperature, and
a dopant for populating the direct bandgap semiconductor material with free-exciton binding centers in a concentration greater than or equal to a native defect concentration in the direct bandgap semiconductor material, wherein the binding energy of either the electron or the hole of each of the free excitons to the dopant binding center is also greater than 25 meV; and
an excitation source or mechanism for generating electron-hole pairs in the direct bandgap semiconductor material to produce substantial populations of excitons;
whereby the binding centers provided by the dopant increase probability of free-exciton to bound-exciton formation in the direct bandgap semiconductor material for generating efficient near-bandgap-emission of light.

2. The structure according to claim 1, wherein the direct bandgap semiconductor material comprises a zinc oxide (ZnO) or zinc oxide alloy polycrystalline thin film.

3. The structure according to claim 2, wherein the dopant comprises aluminum (Al) in an atomic % of up to 20 atomic % for generating a bandgap emission at approximately 385 nm.

4. The structure according to claim 2, wherein the active layer structure comprises a Zn₁₋ₓMgₓO ternary alloy for generating a bandgap emission between 340 nm and 385 nm.

5. The structure according to claim 2, wherein the active layer structure comprises a Zn₁₋ₓCdₓO ternary alloy for generating a bandgap emission between 385 nm and 500 nm.

6. The structure according to claim 2, further comprising a phosphor layer for converting the near bandgap emissions of light from the active layer to visible light.

7. The device according to claim 1, wherein the excitation source comprises a set of electrodes, which includes a first transparent electrode and a second base electrode;
wherein the device further comprises:
a metal electrical contact electrically connected to the transparent electrode for applying the electric field thereto; and
a field oxide region below the electrical contact to minimize current injection below the electrical contact, thereby maximizing current flow in active layer structure adjacent to the metal electrical contact.

8. The structure according to claim 2, wherein the dopant comprises aluminum in an atomic % of between 0.04 at % and 5.0 at %.

9. A method of forming a direct bandgap semiconductor material polycrystalline film comprising the steps of:
a) providing a direct bandgap semiconductor material precursor;
b) providing a dopant precursor for populating crystallites within the polycrystalline film with optically active free-exciton binding centers in concentrations above a native defect concentration;
c) placing the direct bandgap semiconductor material precursor in a solvent with a stabilizing compound forming a mixture;
d) dissolving the dopant precursor in the mixture;
e) dispensing the mixture onto a wafer forming the direct bandgap semiconductor material film with dopant therein; and
f) baking the film to fully crystallize the film, promote grain growth, and minimize the concentration of native intra-crystal defects, thereby substantially increasing the probability that free excitons will encounter and bind to the optically active binding centers before encountering a defect site.

10. The structure according to claim 9, wherein the direct bandgap semiconductor material comprises a zinc oxide (ZnO) or zinc oxide alloy.

11. The method according to claim 10, wherein step b) provides the dopant in an atomic % of up to 20 at %

12. The method according to claim 10, wherein the direct bandgap semiconductor material precursor comprises zinc acetate.

13. The method according to claim 10, wherein the dopant comprises aluminum, and the dopant precursor comprises aluminum nitrate.

14. The method according to claim 9, further comprising passivating any exposed surfaces of the direct bandgap semiconductor material film with a suitable passivant to prevent interaction with ambient air and/or water.

15. The method according to claim 10, further comprising adding magnesium (Mg) acetate after step c), for shifting the bandgap emission wavelength of 385 nm for ZnO downward further into the UV range, whereby Mg substitutes on the Zn atom sub-lattice, forming a Zn₁₋ₓMgₓO ternary alloy.

16. The method according to claim 10, further comprising adding cadmium (Cd) acetate after step c), for shifting the bandgap emission wavelength of 385 nm for ZnO upward into the visible spectrum, whereby Cd substitutes on the Zn atom sub-lattice, forming a Zn₁₋ₓCdₓO ternary alloy.

17. The method according to claim 9, further comprising repeating steps e) and f) resulting in a film thickness between 15 nm and 500 nm.

18. The method according to claim 9, wherein step f) comprises baking the film at 400° C. to 500° C. in air for 60 to 120 minutes, then baking the film at 800° C. to 1200° C. in N₂ for at least 30 minutes.

19. The method according to claim 10, wherein step c) includes providing the dopant precursor comprising aluminum, whereby the direct bandgap semiconductor material polycrystalline film comprises between 0.04 at % and 5.0 at % aluminum.
